(19) United States
(12) Patent Application Publication
(10) Pub. No.: US 2015/0208531 A1
(43) Pub. Date: Jul. 23, 2015

(54) FOOT-STYLE SUPPORTING ASSEMBLY

(71) Applicants: HONG FU JIN PRECISION INDUSTRY (Wuhan) CO., LTD., Wuhan (CN); HON HAI PRECISION INDUSTRY CO., LTD., New Taipei (TW)

(72) Inventors: DA-LONG SUN, Wuhan (CN); YU-GUI CHEN, Wuhan (CN); JUN-ZHI XU, Wuhan (CN)

(21) Appl. No.: 14/498,193

(22) Filed: Sep. 26, 2014

(30) Foreign Application Priority Data
Jan. 20, 2014 (CN) 2014100244805

(51) Int. Cl. H05K 5/02

(52) U.S. Cl. CPC H05K 5/0234

(57) ABSTRACT

A foot stool assembly is disclosed. The foot stool assembly includes a foot stool, a foot pad, a grasping member, and a fastener. The foot pad includes a mounting plate. The fastener secures the mounting plate and the grasping member to the foot stool. The mounting plate is located between the foot stool and the grasping member, preventing the foot pad from coming off the foot stool.

### CROSS-REFERENCE TO RELATED APPLICATIONS

This application claims priority to Chinese Patent Application No. 201410024480.5 filed on Jan. 20, 2014 in the China Intellectual Property Office, the contents of which are incorporated by reference herein.

### FIELD

The subject matter herein generally relates to support assemblies.

### BACKGROUND

A foot stool assembly is generally used in an electronic device, such as an all-in-one machine or a display device, to support the electronic device on a table. Generally, the foot stool assembly includes a foot stool and a foot pad adhesively adhered to the foot stool.

### BRIEF DESCRIPTION OF THE DRAWINGS

Implementations of the present technology will now be described, by way of example only, with reference to the attached figures, wherein:

FIG. 1 is an assembled, isometric view of an embodiment of a foot stool assembly and an electronic device.

FIG. 2 is an exploded, isometric view of the foot stool assembly and the electronic device of FIG. 1.

FIG. 3 is an exploded, isometric view of the foot stool assembly of FIG. 1 showing part of the foot stool assembly.

FIG. 4 is an isometric view of a foot pad of FIG. 3.

FIG. 5 is a cross sectional view of the foot stool assembly and the electronic device taken along a line V-V of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure describes a foot stool assembly including a foot stool, a foot pad, a grasping member, and a fastener. The foot pad includes a mounting plate. The fastener secures the mounting plate and the grasping member to the foot stool. The mounting plate is located between the foot stool and the grasping member, preventing the foot pad from coming off the foot stool.

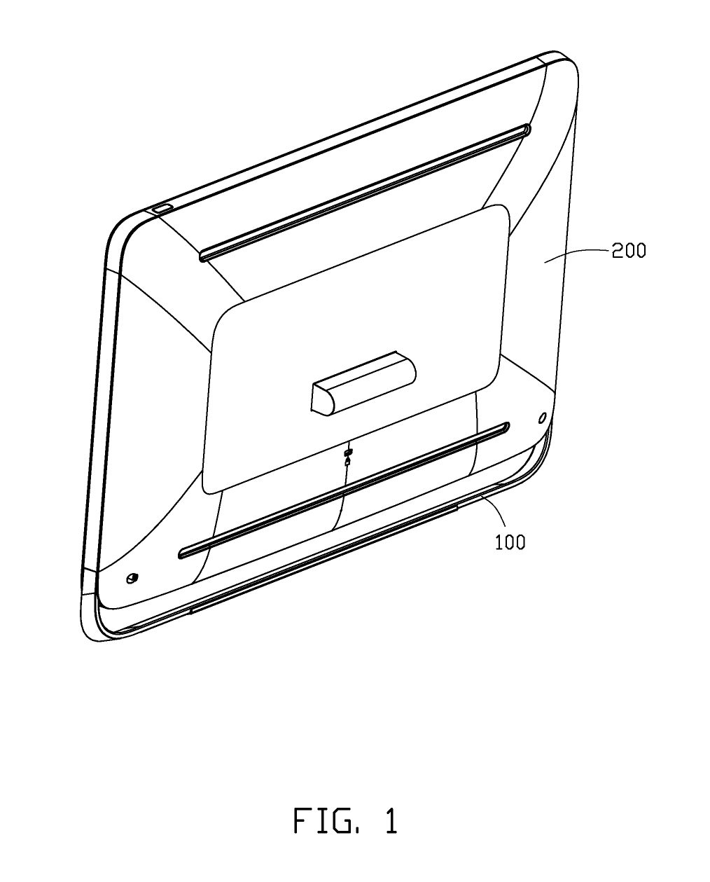

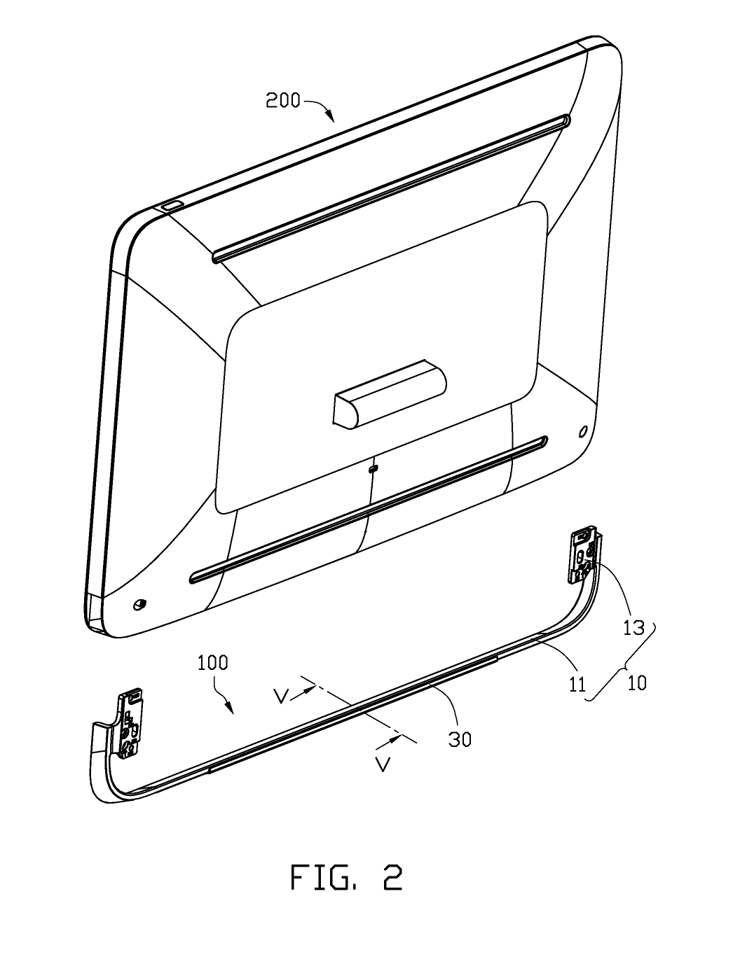

FIGS. 1 and 2 illustrate a foot stool assembly in accordance with an embodiment. The foot stool assembly 100 can be used for supporting an electronic device 200. In at least one embodiment, the electronic device 200 is an all-in-one computer.

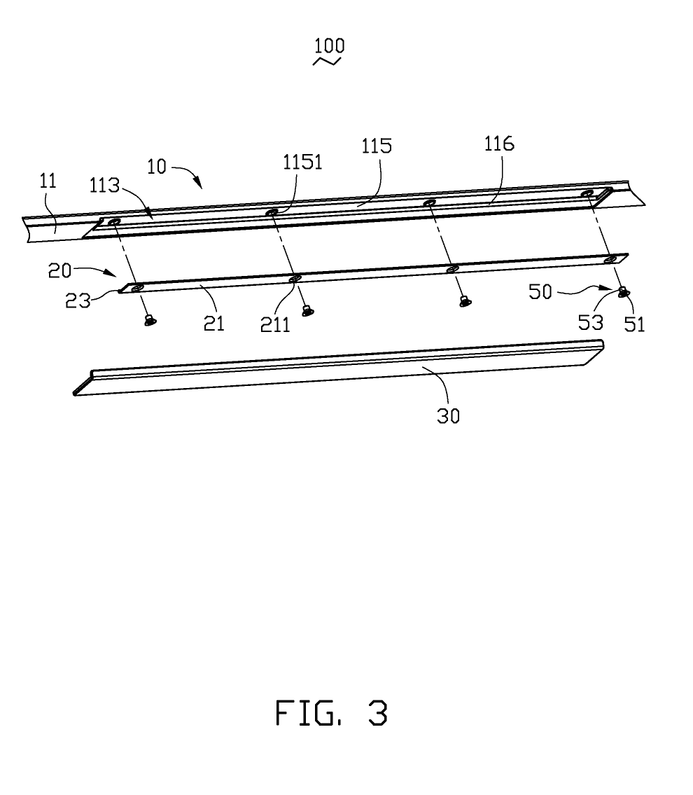

FIGS. 2 and 3 illustrate that the foot stool assembly can include a foot stand, a grasping member, a foot pad, and a plurality of fasteners.

FIG. 3 illustrates that the foot stand 10 includes a supporting portion 11 and two mounting portions 13 extending from opposite ends of the supporting portion 11. The supporting portion 11 defines a slot 113. The slot 113 has a sidewall 115 and a bottom wall 116. In at least one embodiment, the slot 113 is rectangular, and the sidewall 115 is substantially perpendicular to the bottom wall 116. The sidewall 115 defines a plurality of locking holes 1151 corresponding to the fasteners 50.

FIG. 3 also illustrates that the grasping member 20 includes a grasping plate 21 and a flange 23 perpendicularly extending from the grasping plate 21. The grasping plate 21 defines a plurality of through holes 211 corresponding to the locking holes 1151. In at least one embodiment, the flange 23 is substantially perpendicular to the grasping plate 21, and each through hole 211 has a countersink.

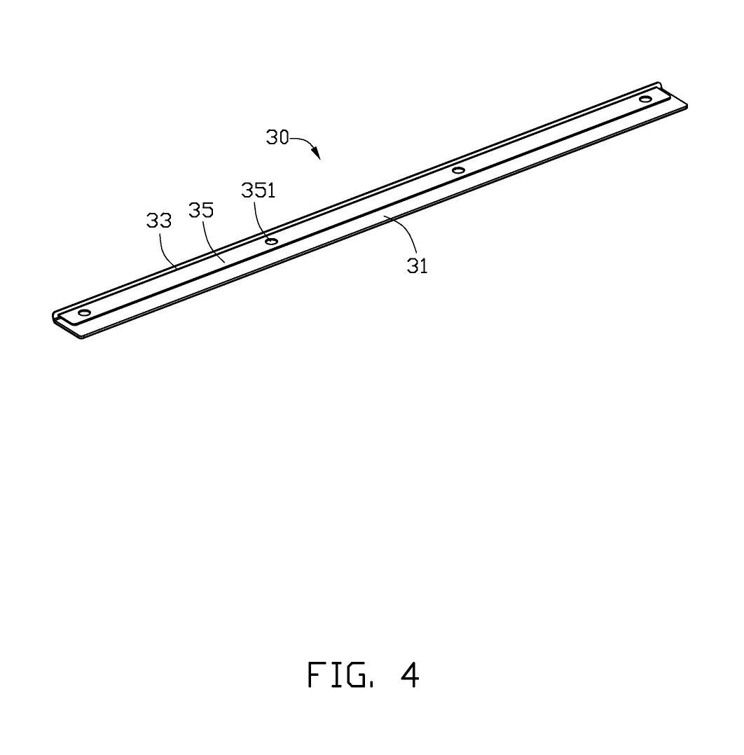

FIGS. 3 and 4 illustrate the foot pad which includes a supporting pad 31, a side pad 33, and a mounting plate 35. The side pad 33 perpendicularly extends from a side of the supporting pad 31. The mounting plate 35 extends from the side pad 33 and is substantially parallel to the supporting pad 31. The mounting plate 35 defines a plurality of mounting holes 351 corresponding to the through holes 211. A height of the side pad 33 is greater than a distance between the mounting plate 35 and the supporting pad 31. The foot stool 30 is made of plastic material. In at least one embodiment, the distance between the mounting plate 35 and the supporting pad 31 is substantially equal to a thickness of the grasping plate 21.

FIG. 3 illustrates that each fastener 50 includes a head portion 51 with a countersink and a neck portion 53. In at least one embodiment, a cross section of each of the head portion 51 and the neck portion 53 is circular. A diameter of the cross section of head portion 51 is greater than a diameter of the cross section of the neck portion 53.

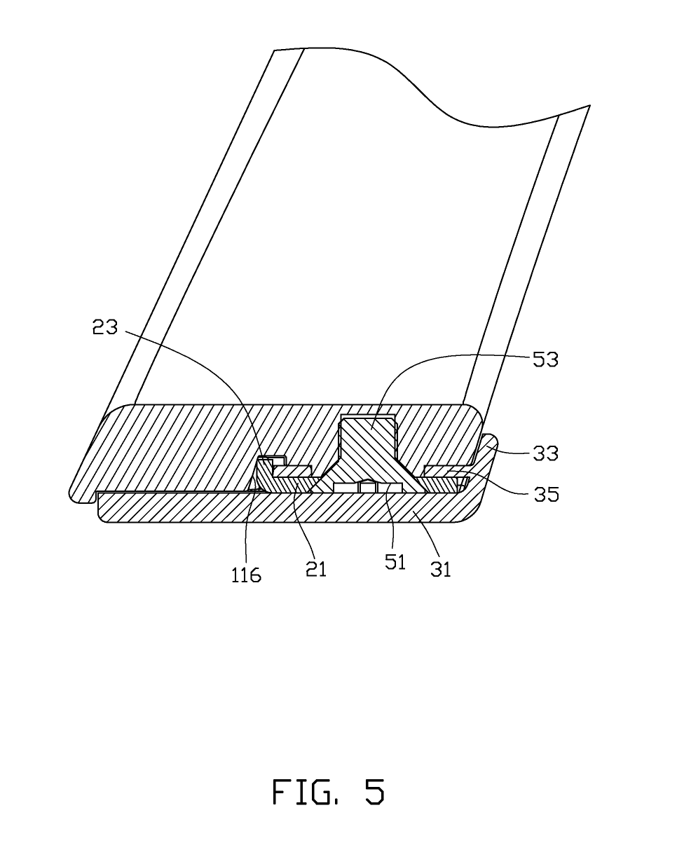

FIGS. 1, 2, and 5 illustrate that in assembly of the foot stool assembly 100, the grasping member 20 is received in the slot 113 with the flange 23 abutting the bottom wall 116, and each through hole 211 is aligned with one of the locking holes 1151. The mounting plate 35 is inserted in the slot 113 between the sidewall 115 and the grasping plate 21. The grasping plate 21 is located between the mounting plate 35 and the supporting pad 31. The mounting plate 35 is substantially parallel to the grasping plate 21 and the sidewall 115. Each mounting hole 351 is aligned with one of the through holes 211. The supporting pad 31 can be elastically deformed away from the mounting plate 35, allowing the fasteners 50 to be positioned between the supporting pad 31 and the mounting plate 35. The neck portion 53 can be flushly locked into the locking hole 1151 through the mounting hole 351 and the through hole 211. The head portion 51 is received in the through hole 211, not extending out of the grasping plate 21. Thus, the mounting plate 35 is attached to the foot stool 10, preventing the foot pad 30 from coming off the foot stool 10. The side pad 33 is configured for covering any gaps between the grasping member 20 and the foot stool 10 and any gaps between the foot pad 30 and the foot stool 10.

The embodiments shown and described above are only examples. Many details are often found in the art such as the other features of a foot stool assembly. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A foot-style supporting assembly comprising:
a foot stool;
a foot pad comprising a mounting plate coupled to the foot stool;
a grasping member coupled to the foot stool; and
a fastener securing the mounting plate and the grasping member to the foot stool;
wherein the mounting plate is located between the foot stool and the grasping member.

2. The supporting assembly of claim 1, wherein the foot stool defines a slot having a sidewall, the grasping member is received in the slot, the grasping member comprises a grasping plate, and the mounting plate is located between the grasping plate and the sidewall.

3. The supporting assembly of claim 2, wherein the slot further has a bottom wall substantially perpendicular to the sidewall, the grasping member further comprises a flange extending from the grasping plate, and the flange abuts against the bottom wall.

4. The supporting assembly of claim 2, wherein the sidewall is substantially parallel to the mounting plate and the grasping plate, and the mounting plate is sandwiched between the mounting plate and the sidewall.

5. The supporting assembly of claim 2, wherein the foot pad further comprises a supporting pad, the supporting pad is substantially parallel to the mounting plate, and the grasping plate is located between the mounting plate and the supporting pad.

6. The supporting assembly of claim 5, wherein a distance between the mounting plate and the supporting pad is substantially equal to a thickness of the grasping plate.

7. The supporting assembly of claim 5, wherein the foot pad further comprises a side pad extending from the supporting pad, the mounting plate extends from the side pad, and the side pad is substantially perpendicular to the supporting pad and the mounting plate.

8. The supporting assembly of claim 7, wherein a height of the side pad is substantially equal to the distance between the mounting plate and the supporting pad.

9. The supporting assembly of claim 2, wherein the mounting plate defines a mounting hole, the fastener comprises a neck portion and a head portion, the neck portion is secured to the sidewall through the mounting hole and the grasping plate, and the head portion is received in the mounting hole without extending out of the mounting hole.

10. The supporting assembly of claim 9, wherein the mounting hole is countersink.

11. A foot-style supporting assembly comprising:
a foot stool defines a slot having a sidewall;
a foot pad comprising a mounting plate; and
a grasping member received in the slot and comprising a grasping plate;
wherein the mounting plate and the grasping member are secured to the foot stool;
the mounting plate is located between the grasping plate and the sidewall.

12. The supporting assembly of claim 11, wherein the slot further has a bottom wall substantially perpendicular to the sidewall, the grasping member further comprises a flange extending from the grasping plate, and the flange abuts against the bottom wall.

13. The supporting assembly of claim 11, wherein the sidewall is substantially parallel to the mounting plate and the grasping plate, and the mounting plate is sandwiched between the mounting plate and the sidewall.

14. The supporting assembly of claim 11, wherein the foot pad further comprises a supporting pad, the supporting pad is substantially parallel to the mounting plate, and the grasping plate is located between the mounting plate and the supporting pad.

15. The supporting assembly of claim 14, wherein a distance between the mounting plate and the supporting pad is substantially equal to a thickness of the grasping plate.

16. The supporting assembly of claim 15, wherein the foot pad further comprises a side pad extending from the supporting pad, the mounting plate extends from the side pad, and the side pad is substantially perpendicular to the supporting pad and the mounting plate.

17. The supporting assembly of claim 16, wherein a height of the side pad is substantially equal to the distance between the mounting plate and the supporting pad.

18. The supporting assembly of claim 11, further comprising a fastener, wherein the fastener secures the mounting plate and the grasping member to the foot stool.

19. The supporting assembly of claim 18, wherein the mounting plate defines a mounting hole, the fastener comprises a neck portion and a head portion, the neck portion is secured to the sidewall through the mounting hole and the grasping plate, and the head portion is received in the mounting hole without extending out of the mounting hole.

20. The supporting assembly of claim 19, wherein the mounting hole is countersink.
